(19) United States
(12) Patent Application Publication
(10) Pub. No.: US 2016/0329419 A1
(43) Pub. Date: Nov. 10, 2016

(54) NITRIDE SEMICONDUCTOR LAYERED BODY, METHOD FOR MANUFACTURING THE SAME, AND NITRIDE SEMICONDUCTOR DEVICE

(71) Applicant: SHARP KABUSHIKI KAISHA, Sakai City, Osaka (JP)

(72) Inventors: Atsushi OGAWA, Osaka-shi (JP); Manabu TOHSAKI, Osaka-shi (JP); Yohsuke FUJISHIGE, Osaka-shi (JP); Nobuyuki ITO, Osaka-shi (JP); Mai OKAZAKI, Osaka-shi (JP); Yushi INOUE, Osaka-shi (JP); Masayuki TAJIRI, Osaka-shi (JP); Nobuaki TERAGUCHI, Osaka-shi (JP)

(73) Assignee: SHARP KABUSHIKI KAISHA, Sakai City, Osaka (JP)

(21) Appl. No.: 15/100,557

(22) PCT Filed: Jan. 6, 2015
(86) PCT No.: PCT/JP2015/050129

§ 371 Date: May 31, 2016

(30) Foreign Application Priority Data
Jan. 31, 2014 (JP) 2014-016694
Apr. 24, 2014 (JP) 2014-090422

(51) Int. Cl. H01L 29/778; H01L 29/66; H01L 29/04; H01L 21/02; H01L 29/20; H01L 29/205

(52) U.S. Cl. CPC H01L 29/7786; H01L 29/2003; H01L 29/205; H01L 29/045; H01L 21/0254; H01L 21/02381; H01L 21/02433; H01L 21/02458; H01L 21/02505; H01L 21/0262; H01L 29/66462

(57) ABSTRACT

A nitride semiconductor layered body includes a Si substrate having a surface, as the principal surface, inclined at an off-angle of 0 degrees or more and 4.0 degrees or less with respect to a plane and a nitride semiconductor layer disposed on the Si substrate.

### TECHNICAL FIELD

The present invention relates to a nitride semiconductor layered body, a method for manufacturing the same, and a nitride semiconductor device.

### BACKGROUND ART

A nitride semiconductor is represented by a general formula InₓAl_{y}Ga_{1-x-y}N (0≦x≦1, 0≦y≦1, and 0≦x+y≦1). Regarding this nitride semiconductor, the band gap can be changed within the range of 1.95 eV to 6 eV depending on the composition thereof. Therefore, the nitride semiconductor has been researched and developed as a material for light-emitting devices in a wide wavelength range from an ultraviolet region to an infrared region and has been commercialized.

Also, a control device including the nitride semiconductor has been used for power elements and the like which are operated at high frequencies and, in addition, high outputs. Most of all, for example, FETs, e.g., a high electron mobility field-effect transistor (HEMT), suitable for amplification in high frequency bands are known.

Japanese Unexamined Patent Application Publication No. 2008-166349 (PTL 1) describes a nitride semiconductor layered body in related art. In this nitride semiconductor layered body in related art, an AlN layer serving as a barrier layer, an AlGaN layer, which serves as a buffer layer and in which an Al composition is changed in the layer thickness direction, and a GaN layer are sequentially epitaxially grown on a Si substrate.

In the above-described nitride semiconductor layered body in related art, the AlN layer serving as a barrier layer is disposed between the Si substrate and the GaN layer because Si reacts with Ga easily. However, if the GaN layer is grown directly on the AlN layer, warping or cracking occurs easily and it is not possible to obtain a good GaN layer. Therefore, an AlGaN layer, in which the Al composition is changed in the layer thickness direction, is interposed between the AlN layer and the GaN layer.

### CITATION LIST

### Patent Literature

PTL 1: Japanese Unexamined Patent Application Publication No. 2008-166349

### SUMMARY OF INVENTION

### Technical Problem

However, the above-described nitride semiconductor layered body in related art has a problem that the mobility of electrons generated in the vicinity of a 2DEG layer (two-dimensional electron gas layer) is small, a depletion region is generated when a voltage is applied and, thereby, on resistance increases.

Accordingly, it is an issue of the present invention to provide a nitride semiconductor device in which an increase in on-resistance can be suppressed by improving the mobility of electrons generated in the vicinity of a 2DEG layer.

### Solution to Problem

In order to solve the above-described issue, a nitride semiconductor layered body according to the present invention includes

a Si substrate having a surface, as a principal surface, inclined at an off-angle of 0 degrees or more and 4.0 degrees or less with respect to a (111) plane, and

a nitride semiconductor layer disposed on the Si substrate.

In the present specification, the term nitride semiconductor refers to, for example, GaN, AlN, AlGaN, and InGaN and refers to, in particular, semiconductors Represented by a general formula InₓAl_{y}Ga_{1-x-y}N (0≦x≦1, 0≦Y≦1, and 0≦x+y≦1).

### Advantageous Effects of Invention

According to the present invention, the mobility of electrons generated in the vicinity of a 2DEG layer can be improved. Therefore, it is possible to suppress an increase in on-resistance of the nitride semiconductor device and reduce current collapse.

### BRIEF DESCRIPTION OF DRAWINGS

FIG. 1 is a schematic sectional view of a nitride semiconductor layered body according to a first embodiment of the present invention.

FIG. 2 is a schematic sectional view of a nitride semiconductor layered body according to a second embodiment of the present invention.

FIG. 3 is a schematic sectional view of a nitride semiconductor layered body according to a third embodiment of the present invention.

FIG. 4 is a schematic sectional view of a nitride semiconductor layered body according to a fourth embodiment of the present invention.

FIG. 5 is a schematic sectional view of a nitride semiconductor device according to a fifth embodiment of the present invention.

FIG. 6 is a schematic diagram of an upper surface of the nitride semiconductor device.

FIG. 7 is a magnified schematic diagram of the upper surface shown in FIG. 6.

FIG. 8 is a diagram showing Si atomic layer steps of the nitride semiconductor device.

### DESCRIPTION OF EMBODIMENTS

The present invention will be described below in detail with reference to the embodiments shown in the drawings.

### First Embodiment

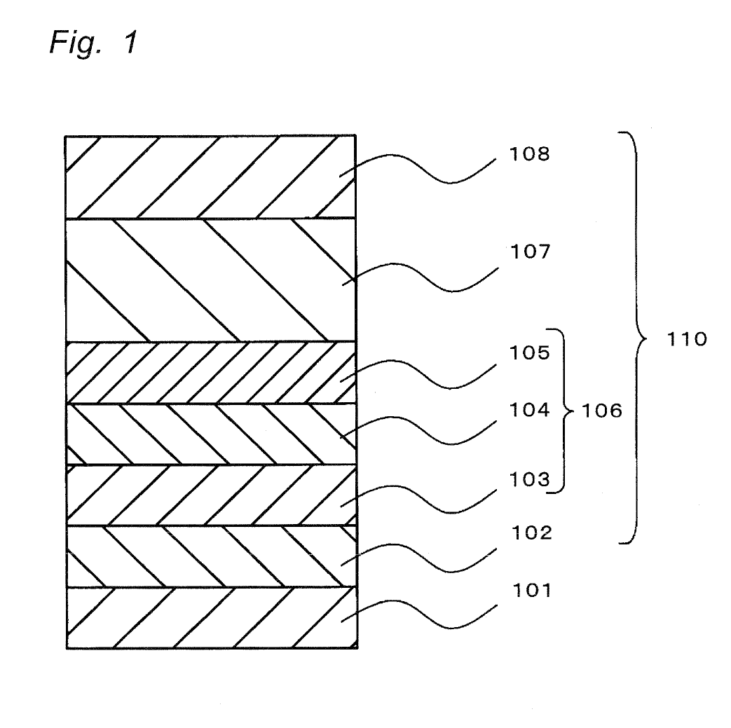

FIG. 1 is a schematic sectional view of a nitride semiconductor layered body according to a first embodiment of the present invention. As shown in FIG. 1, the nitride semiconductor layered body according to the first embodiment includes a Si substrate 101 and a nitride semiconductor layer 110 disposed on the Si substrate 101. An AlN buffer layer 102 is disposed on a principal surface of the Si substrate 101.

The principal surface of the Si substrate 101 is a surface inclined at an off-angle of 0.8 degrees or more and 2.7 degrees or less with respect to a (111) plane in a (011) plane direction. In addition, the surface of the Si substrate 101 is roughened such that the above-described principal surface is present in a region constituting 30% of the above-described surface region.

The AlN buffer layer 102 is an AlN layer exhibiting a half-width of a rocking curve based on X-ray diffraction of the (0002) plane of 1,900 arcsec.

An AlGaN buffer layer 106, in which an AlGaN-1 layer 103, an AlGaN-2 layer 104, and an AlGaN-3 layer 105 are stacked sequentially, is disposed on the AlN buffer layer 102. A GaN layer 107 is disposed on the AlGaN buffer layer 106, and an AlGaN barrier layer 108 is disposed on the GaN layer 107. These AlN buffer layer 102, AlGaN buffer layer 106, GaN layer 107, and AlGaN barrier layer 108 constitute the nitride semiconductor layer 110.

Next, a method for manufacturing the above-described nitride semiconductor layered body will be described below.

Initially, a surface oxide film of the Si substrate 101 is removed with dilute hydrofluoric acid.

Subsequently, the Si substrate 101 is introduced into a reactor of a MOCVD (metal organic chemical vapor deposition) apparatus. After the temperature of the Si substrate 101 is raised to 1,100° C., NH₃ (ammonia) and TMA (trimethylaluminum) are supplied so as to form the AlN buffer layer 102 having a thickness of 180 nm on the principal surface of the Si substrate 101 through epitaxial growth at a growth rate of 400 nm/hr.

Then, NH₃, TMA, and TMG (trimethyl gallium) are supplied while the temperature of the Si substrate 101 is maintained at 1,100° C. so as to form the AlGaN-1 layer 103 having a thickness of 200 nm, the AlGaN-2 layer 104 having a thickness of 300 nm, and the AlGaN-3 layer 105 having a thickness of 400 nm sequentially on the AlN buffer layer 102 through epitaxial growth. The Al composition ratio in the AlGaN buffer layer 106 is 50%.

Subsequently, NH₃ and TMG are supplied while the temperature of the Si substrate 101 is maintained at 1,100° C. so as to form the GaN layer 107 having a thickness of 1,000 nm on the AlGaN buffer layer 106 through epitaxial growth.

Thereafter, the temperature of the Si substrate 101 is set at 1,050° C., NH₃, TMA, and TMG are supplied so as to form the AlGaN barrier layer 108 having a thickness of 30 nm on the GaN layer 107 through epitaxial growth.

In this manner, the nitride semiconductor layered body according to the first embodiment is produced.

Next, eight samples were produced, which were Example 1-1 to Example 1-5 as samples of the nitride semiconductor layered bodies according to the first embodiment of the present invention and Comparative example 1-1 to Comparative example 1-3 as samples of comparative examples of the first embodiment.

### Example 1-1

Four Si substrates, each having a surface, as a principal surface, inclined at an off-angle of 0.8 degrees to 1.1 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body.

### Example 1-2

Four Si substrates, each having a surface, as a principal surface, inclined at an off-angle of 1.2 degrees to 1.5 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body. As described above, the nitride semiconductor layered body in Example 1-2 has the same structure as the structure of the nitride semiconductor layered body in Example 1-1 except that the off-angle of the Si substrate 101 is different from the off-angle of the Si substrate 101 in Example 1-1.

### Example 1-3

Four Si substrates, each having a surface, as a principal surface, inclined at an off-angle of 1.6 degrees to 1.9 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body. As described above, the nitride semiconductor layered body in Example 1-3 has the same structure as the structure of the nitride semiconductor layered body in Example 1-1 except that the off-angle of the Si substrate 101 is different from the off-angle of the Si substrate 101 in Example 1-1.

### Example 1-4

Four Si substrates, each having a surface, as a principal surface, inclined at an off-angle of 2.0 degrees to 2.3 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body. As described above, the nitride semiconductor layered body in Example 1-4 has the same structure as the structure of the nitride semiconductor layered body in Example 1-1 except that the off-angle of the Si substrate 101 is different from the off-angle of the Si substrate 101 in Example 1-1.

### Example 1-5

Four Si substrates, each having a surface, as a principal surface, inclined at an off-angle of 2.4 degrees to 2.7 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body. As described above, the nitride semiconductor layered body in Example 1-5 has the same structure as the structure of the nitride semiconductor layered body in Example 1-1 except that the off-angle of the Si substrate 101 is different from the off-angle of the Si substrate 101 in Example 1-1.

### Comparative Example 1-1

Four Si substrates, each having a surface, as a principal surface, inclined at an off-angle of 0.5 degrees to 0.7 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body. As described above, the nitride semiconductor layered body in Comparative example 1-1 has the same structure as the structure of the nitride semiconductor layered body in Example 1-1 except that the off-angle of the Si substrate 101 is different from the off-angle of the Si substrate 101 in Example 1-1.

### Comparative Example 1-2

Four Si substrates, each having a surface, as a principal surface, inclined at an off-angle of 2.8 degrees to 3.1 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body. As described above, the nitride semiconductor layered body in Comparative example 1-2 has the same structure as the structure of the nitride semiconductor layered body in Example 1-1 except that the off-angle of the Si substrate 101 is different from the off-angle of the Si substrate 101 in Example 1-1.

### Comparative Example 1-3

Four Si substrates, each having a surface, as a principal surface, inclined at an off-angle of 3.2 degrees to 3.5 degrees with respect to the (111) plane in the (011) plane direction, are prepared as the Si substrates 101. A nitride semiconductor layer is formed on each of the Si substrates 101 by the manufacturing method according to the first embodiment so as to produce a sample of a nitride semiconductor layered body. As described above, the nitride semiconductor layered body in Comparative example 1-3 has the same structure as the structure of the nitride semiconductor layered body in Example 1-1 except that the off-angle of the Si substrate 101 is different from the off-angle of the Si substrate 101 in Example 1-1.

Regarding each of samples of Example 1-1 to Example 1-5 and Comparative example 1-1 to Comparative example 1-3, the surface flatness on an area of 100 μm×100 μm basis was calculated by using AFM (atomic force microscope) and is shown in Table 1. Here, the surface flatness is a value determined by averaging the differences between the maximum height of projected portions and the minimum height of recessed portions on the surface of the above-described area.

TABLE 1

| | Off-angle | |
|---|---|---|
| | (degree) | Surface flatness (nm) |
| Comparative example 1-1 | 0.5 to 0.7 | 51.5 |
| Example 1-1 | 0.8 to 1.1 | 25.2 |
| Example 1-2 | 1.2 to 1.5 | 21.3 |
| Example 1-3 | 1.6 to 1.9 | 12.6 |
| Example 1-4 | 2.0 to 2.3 | 19.8 |
| Example 1-5 | 2.4 to 2.7 | 23.3 |
| Comparative example 1-2 | 2.8 to 3.1 | 61.5 |
| Comparative example 1-3 | 3.2 to 3.5 | 82.2 |

As shown in Table 1, the surface flatness of each of samples of Example 1-1 to Example 1-5 is 25.2 nm or less. The surface flatness of the sample of Example 1-1 is about half the surface flatness of the sample of Comparative example 1-1. The reason for this is as described below. The terrace width of the growth surface decreases compared with the case where the principal surface of the Si substrate is a surface inclined at an off-angle of less than 0.8 degrees with respect to the (111) plane in the (011) plane direction. Even in the case where a growth temperature is relatively low, the distance of migration of a precursor, which is an atom or a molecule before growth, is small. Therefore, step-flow growth occurs easily, the tendency of the precursor to stop at some midpoint in a terrace and start nucleation in a crystal orientation different from the orientation of the step flow is reduced. As a result, growth of hillock-like projections is suppressed so as to reduce surface unevenness.

On the other hand, the surface flatness of the sample of Comparative example 1-2 is about 3 times the surface flatness of the sample of Example 1-5. The reason for this is as described below. In the case where the principal surface of the Si substrate is a surface inclined at an off-angle of more than 2.7 degrees with respect to the (111) plane in the (011) plane direction, the terrace width of the growth surface excessively decreases, step-flow growth excessively proceeds, the atomic balance between step-flow growth and release from the surface is lost, and irregular growth proceeds such that, for example, a group III atom occupies a position which should be the position of a group V site. Then, this irregular growth causes surface roughening, e.g., growth of hillock-like projections.

Meanwhile, in the case where a nitride semiconductor layered body including an epitaxial film having unevenness including hillock-like projections is produced, dislocation of an antiphase boundary portion at an interface between a “crystal constituting a hillock-like projection” and a “crystal in a step-flow growth area” and a difference in process, e.g., photolithography, due to height differences of the surface occur. It is considered that these lead to leakage, in-plane unevenness, and the like, so as to degrade the performance of the nitride semiconductor layered body.

Therefore, it is preferable that the principal surface of the Si substrate 101 have an off-angle of 0.8 degrees or more and 2.7 degrees or less with respect to the (111) plane. In this case, the terrace width of the growth surface decreases compared with the terrace width in the case where the off-tangle is less than 0.8 degrees with respect to the (111) plane. Even in the case where a growth temperature is relatively low, the distance of migration of a precursor, which is an atom or a molecule before growth, is small. Therefore, step-flow growth occurs easily, the tendency of the precursor to stop at some midpoint in a terrace and start nucleation in a crystal orientation different from the orientation of the step flow is reduced. As a result, growth of hillock-like projections can be suppressed and surface unevenness can be reduced.

Also, the terrace width does not excessively decreases compared with the case where the off-angle is more than 2.7 degrees with respect to the (111) plane, and it is possible to prevent irregular growth such as, for example, occupation of a position, which should be the position of a group V site, by a group III atom because of excessive proceeding of step-flow growth and loss of the atomic balance between step-flow growth and release from the surface. As a result, growth of hillock-like projections can be suppressed and surface unevenness can be reduced.

Meanwhile, in the case where a nitride semiconductor layered body including an epitaxial film having reduced unevenness including hillock-like projections is produced, occurrences of dislocation of an antiphase boundary portion at an interface between a “crystal constituting a hillock-like projection” and a “crystal in a step-flow growth area” and a difference in process, e.g., photolithography, due to height differences of the surface can be prevented. Consequently, leakage, in-plane unevenness, and the like can be prevented.

Therefore, the surface flatness of the nitride semiconductor layer 110 can be improved and a high-performance nitride semiconductor layered body can be produced.

Also, roughening is performed such that the principal surface of the Si substrate 101 is present in a region constituting 30% of the above-described surface region. Consequently, in the above-described region, the terrace width of the growth surface decreases, warping of the Si substrate 101 due to a difference in lattice constant between Si and AlN is suppressed more reliably, application of strain stress to the AlN buffer layer can be suppressed, and occurrences of pits can be reduced more reliably. Therefore, growth of hillock-like projections can be suppressed, the surface flatness of the nitride semiconductor layer 110 can be improved more reliably, and a high-performance nitride semiconductor layered body can be produced more reliably.

### Second Embodiment

Next, a nitride semiconductor layered body according to a second embodiment of the present invention will be described.

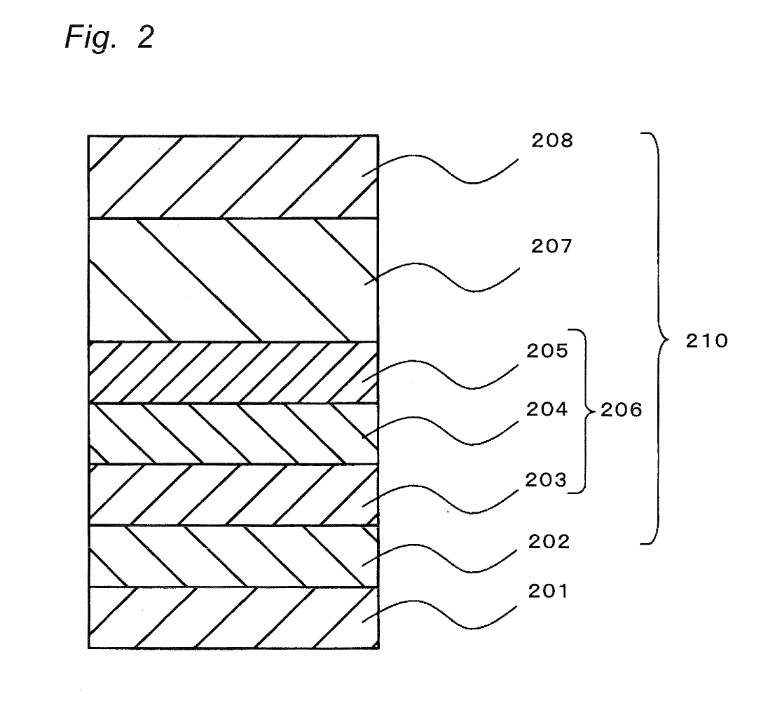

FIG. 2 is a schematic sectional view of a nitride semiconductor layered body according to the second embodiment. As shown in FIG. 2, the nitride semiconductor layered body according to the second embodiment is formed by the same method as the manufacturing method in the first embodiment. That is, an AlN buffer layer 202 is disposed on a principal surface of a Si substrate 201. The AlN buffer layer 202 is an AlN layer exhibiting a half-width of a rocking curve based on X-ray diffraction of the (0002) plane of 1,900 arcsec.

An AlGaN buffer layer 206, in which an AlGaN-1 layer 203, an AlGaN-2 layer 204, and an AlGaN-3 layer 205 are stacked sequentially, is disposed on the AlN buffer layer 202. The Al composition ratio in the AlGaN buffer layer 206 is 50%.

A GaN layer 207 having a thickness of 1,000 nm is disposed on the AlGaN buffer layer 206, and an AlGaN barrier layer 208 is disposed on the GaN layer 207. These AlN buffer layer 202, AlGaN buffer layer 206, GaN layer 207, and AlGaN barrier layer 208 constitute a nitride semiconductor layer 210.

Next, seven samples were produced, which were Example 2-1 to Example 2-4 as samples of the nitride semiconductor layered bodies of the second embodiment and Comparative example 2-1 to Comparative example 2-3 as samples of comparative examples of the second embodiment.

### Example 2-1

Four Si substrates, each having a surface, as a principal surface, inclined at an off-angle of 2.0 degrees with respect to the (111) plane in the (011) plane direction, are prepared as the Si substrates 201. A nitride semiconductor layer 210 is formed on each of the Si substrates 201 by the above-described manufacturing method so as to produce a sample of a nitride semiconductor layered body. Here, the thickness of the AlN buffer layer 202 is 50 nm.

### Example 2-2

A nitride semiconductor layered body in Example 2-2 has the same structure as the structure of the nitride semiconductor layered body in Example 2-1 except that the thickness of the AlN buffer layer 202 is 100 nm.

### Example 2-3

A nitride semiconductor layered body in Example 2-3 has the same structure as the structure of the nitride semiconductor layered body in Example 2-1 except that the thickness of the AlN buffer layer 202 is 180 nm.

### Example 2-4

A nitride semiconductor layered body in Example 2-4 has the same structure as the structure of the nitride semiconductor layered body in Example 2-1 except that the thickness of the AlN buffer layer 202 is 400 nm.

### Comparative Example 2-1

A nitride semiconductor layered body in Comparative example 2-1 has the same structure as the structure of the nitride semiconductor layered body in Example 2-1 except that the thickness of the AlN buffer layer 202 is 40 nm.

### Comparative Example 2-2

A nitride semiconductor layered body in Comparative example 2-2 has the same structure as the structure of the nitride semiconductor layered body in Example 2-1 except that the thickness of the AlN buffer layer 202 is 450 nm.

### Comparative Example 2-3

A nitride semiconductor layered body in Comparative example 2-3 has the same structure as the structure of the nitride semiconductor layered body in Example 2-1 except that the thickness of the AlN buffer layer 202 is 500 nm.

The surface state of the AlGaN buffer layer 206 in the sample of each of Example 2-1 to Example 2-4 and Comparative example 2-1 to Comparative example 2-3 was observed by SEM (scanning electron microscope). Subsequently, an average number of pits on an area of 100 μm² basis of the surface of the AlGaN buffer layer 206 was calculated. The average numbers are shown in Table 2. Here, the above-described pit refer to a pit having a size of 10 nm or more and 50 nm or less in diameter in the above-described area. The pit has a harmful influence, e.g., leakage, on the characteristics of the nitride semiconductor layered body.

TABLE 2

| | Film thickness of AlN | |
|---|---|---|
| | layer (nm) | Number of pits |
| Comparative example 2-1 | 40 | 25.6 |
| Example 2-1 | 50 | 1.3 |
| Example 2-2 | 100 | 0.8 |
| Example 2-3 | 180 | 0.5 |
| Example 2-4 | 400 | 1.4 |
| Comparative example 2-2 | 450 | 13.8 |
| Comparative example 2-3 | 500 | 21.7 |

As shown in Table 2, the number of pits in the sample of each of Example 2-1 to Example 2-4 is 1.4 or less. In this regard, the number of pits in the sample of Comparative example 2-1 is 25.6, that is, about 20 times the number of pits of the sample of Example 2-1. The reason for this is considered as described below. In the case where the thickness of the AlN buffer layer 202 is less than 50 nm, the AlN buffer layer 202 does not sufficiently function as a cover layer. Consequently, Ga of TMG used for epitaxial growth of the AlGaN buffer layer 206 reacts with the Si substrate 201 so as to roughen the surface of the Si substrate 201, and a threading dislocation, which causes generation of a pit and the like, occurs easily.

Meanwhile, the number of pits in the sample of Comparative example 2-2 is 13.8, that is, about 10 times the number of pits of the sample of Example 2-4. The reason for this is considered as described below. In the case where the thickness of the AlN buffer layer 202 is more than 400 nm, the extent of warp of the Si substrate 201 increases because of a difference in lattice constant between Si and AlN during growth of the AlN buffer layer 202 and the AlGaN buffer layer 206. Then, strain stress is applied to the AlN buffer layer 202 and the AlGaN buffer layer 206 and, thereby, pits are generated in the AlN buffer layer 202 easily.

Therefore, the thickness of the AlN buffer layer 202 on the Si substrate 201 is preferably 50 nm or more and 400 nm or less. In the case where the thickness of the AlN buffer layer 202 is 50 nm or more, the AlN buffer layer 202 functions as a cover layer sufficiently. Consequently, when the GaN layer 207 is stacked on the AlN buffer layer 202, the reaction between Si and Ga can be suppressed. Further, growth of hillock-like projections can be suppressed and, in addition, occurrences of threading dislocations, which cause generation of pits, can be reduced.

Also, the thickness of the AlN buffer layer 202 is 400 nm or less, warping of the Si substrate 201 due to a difference in lattice constant between Si and AlN is suppressed, strain stress applied to the AlN buffer layer 202 can be reduced, and generation of pits in the AlN buffer layer 202 can be reduced.

### Third Embodiment

Next, a nitride semiconductor layered body according to a third embodiment of the present invention will be described.

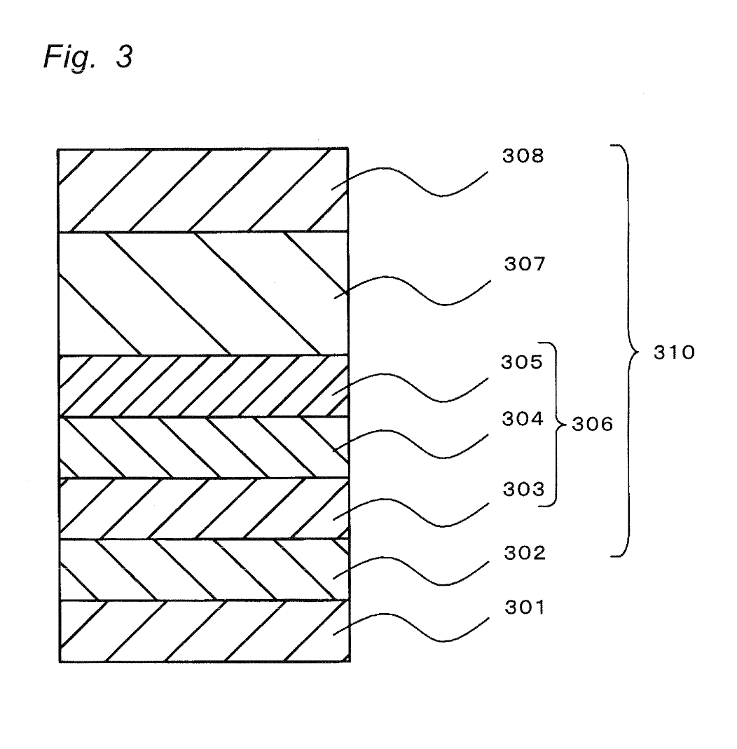

FIG. 3 is a schematic sectional view of a nitride semiconductor layered body according to the third embodiment. As shown in FIG. 3, the nitride semiconductor layered body according to the third embodiment is formed by the same method as the manufacturing method in the first embodiment. That is, an AlN buffer layer 302 having a thickness of 180 nm is disposed on a principal surface of a Si substrate 301. An AlGaN buffer layer 306, in which an AlGaN-1 layer 303, an AlGaN-2 layer 304, and an AlGaN-3 layer 305 are stacked sequentially, is disposed on the AlN buffer layer 302. The Al composition ratio in the AlGaN buffer layer 306 is 50%.

A GaN layer 307 having a thickness of 1,000 nm is disposed on the AlGaN buffer layer 306, and an AlGaN barrier layer 308 is disposed on the GaN layer 307. These AlN buffer layer 302, AlGaN buffer layer 306, GaN layer 307, and AlGaN barrier layer 308 constitute a nitride semiconductor layer 310.

Next, four samples were produced, which were Example 3-1 to Example 3-3 as samples of the nitride semiconductor layered bodies according to the third embodiment and Comparative example 3-1 as a sample of a comparative example of the third embodiment.

### Example 3-1

Four Si substrates, each having a surface, as a principal surface, inclined at an off-angle of 2.0 degrees with respect to the (111) plane in the (011) plane direction, are prepared as the Si substrates 301. A nitride semiconductor layer 310 is formed on each of the Si substrates 301 by the above-described manufacturing method so as to produce a sample of a nitride semiconductor layered body. Here, the growth rate of the AlN buffer layer 302 is changed. The half-width of a rocking curve based on X-ray diffraction of the (0002) plane of the AlN buffer layer 302 is 1,900 arcsec.

In this regard, the half-width of a rocking curve based on X-ray diffraction of the (0002) plane of the AlN buffer layer 302 reflects the results of a preliminary experiment, in which semiconductor layered bodies were produced by growing an AlN buffer layer having a thickness of 180 nm on a Si substrate at various growth rates and the resulting semiconductor layered bodies were subjected to X-ray diffraction evaluation.

### Example 3-2

A nitride semiconductor layered body in Example 3-2 has the same structure as the structure of the nitride semiconductor layered body in Example 3-1 except that the half-width of a rocking curve based on X-ray diffraction of the (0002) plane of the AlN buffer layer 302 is 2,200 arcsec.

### Example 3-3

A nitride semiconductor layered body in Example 3-3 has the same structure as the structure of the nitride semiconductor layered body in Example 3-1 except that the half-width of a rocking curve based on X-ray diffraction of the (0002) plane of the AlN buffer layer 302 is 2,500 arcsec.

### Comparative Example 3-1

A nitride semiconductor layered body in Comparative example 3-1 has the same structure as the structure of the nitride semiconductor layered body in Example 3-1 except that the half-width of a rocking curve based on X-ray diffraction of the (0002) plane of the AlN buffer layer 302 is 2,650 arcsec.

The surface state of the AlGaN buffer layer 306 in the sample of each of Example 3-1 to Example 3-3 and Comparative example 3-1 was observed by SEM. Subsequently, an average number of pits on an area of 100 μm² basis of the surface of the AlGaN buffer layer 306 was calculated. The average numbers are shown in Table 3.

TABLE 3

| | Half-width of rocking | |
|---|---|---|
| | curve (arcsec) | Number of pits |
| Example 3-1 | 1900 | 0.5 |
| Example 3-2 | 2200 | 0.8 |
| Example 3-3 | 2500 | 1.8 |
| Comparative example 3-1 | 2650 | 12.3 |

As shown in Table 3, the number of pits in the sample of each of Example 3-1 to Example 3-3 is 1.8 or less. In this regard, the number of pits in the sample of Comparative example 3-1 is 12.3, that is, about 7 times the number of pits of the sample of Example 3-3. The reason for this is considered as described below. The half-width of a rocking curve based on X-ray diffraction of the (0002) plane of the AlN buffer layer 302 is more than 2,500 arcsec, the crystallinity of the AlN buffer layer 302 is poor and, thereby, threading dislocations, which cause generation of pits, and the like occur easily.

Therefore, the half-width of a rocking curve based on X-ray diffraction of the (0002) plane of the AlN buffer layer 302 is preferably 2,500 arcsec or less. In the case where the half-width of a rocking curve is 2,500 arcsec or less, occurrences of dislocations are reduced, and when the GaN layer 307 is stacked on the AlN buffer layer 302, the reaction between Si and Ga can be suppressed. Also, the half-width of a rocking curve is 2,500 arcsec or less and, therefore, the crystallinity of the AlN buffer layer 302 is good, occurrences of dislocations are reduced, and generation of pits can be reduced. Consequently, the surface flatness of the nitride semiconductor layer 310 can be improved more reliably, and a high-performance nitride semiconductor layered body can be produced more reliably.

### Fourth Embodiment

Next, a nitride semiconductor layered body according to a fourth embodiment of the present invention will be described.

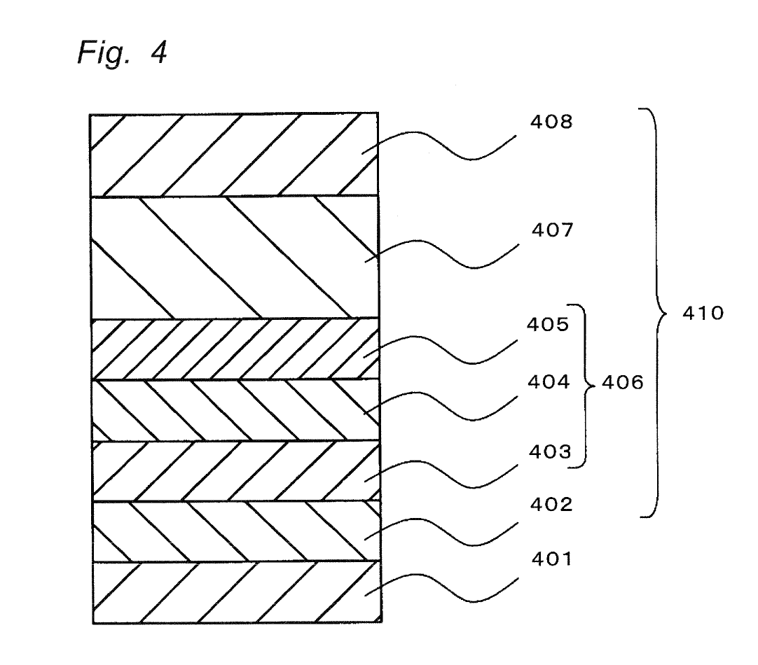

FIG. 4 is a schematic sectional view of a nitride semiconductor layered body according to the fourth embodiment. As shown in FIG. 4, the nitride semiconductor layered body according to the fourth embodiment is formed by the same method as the manufacturing method in the first embodiment. That is, an AlN buffer layer 402 is disposed on a principal surface of a Si substrate 401.

The AlN buffer layer 102 is an AlN buffer layer exhibiting a half-width of a rocking curve based on X-ray diffraction of the (0002) plane of 1,900 arcsec.

An AlGaN buffer layer 406, in which an AlGaN-1 layer 403, an AlGaN-2 layer 404, and an AlGaN-3 layer 405 are stacked sequentially, is disposed on the AlN buffer layer 402. A GaN layer 407 is disposed on the AlGaN buffer layer 406, and an AlGaN barrier layer 408 is disposed on the GaN layer 407. These AlN buffer layer 402, AlGaN buffer layer 406, GaN layer 407, and AlGaN barrier layer 408 constitute a nitride semiconductor layer 410.

Next, a method for manufacturing the nitride semiconductor layered body according to the fourth embodiment will be described below.

Initially, the AlN buffer layer 402 having a thickness of 180 nm is disposed on a principal surface of the Si substrate 401, and the AlGaN-1 layer 403 having a thickness of 200 nm, the AlGaN-2 layer 404 having a thickness of 300 nm, and the AlGaN-3 layer 405 having a thickness of 400 nm are stacked sequentially on the AlN buffer layer 402 in the same manner as the method for manufacturing the nitride semiconductor layered body, according to the first embodiment. Here, in the method for manufacturing the nitride semiconductor layered body, according to the fourth embodiment, the Al composition ratio in the AlGaN buffer layer 406 is 20%.

Subsequently, NH₃ and TMG are supplied while the temperature of the Si substrate 401 is maintained at 1,100° C. so as to form the GaN layer 407 having a thickness of 200 nm on the AlGaN buffer layer 406 through epitaxial growth.

Thereafter, the temperature of the Si substrate 401 is maintained at 1,100° C., NH₃, TMG, and TMA are supplied so as to form the AlGaN barrier layer 408 having a thickness of 25 nm and an Al composition ratio of 10% on the GaN layer 407 through epitaxial growth.

In this manner, the nitride semiconductor layered body according to the fourth embodiment is produced.

Next, six samples were produced, which were Example 4-1 to Example 4-3 as samples of the nitride semiconductor layered bodies of the fourth embodiment and Comparative example 4-1 to Comparative example 4-3 as samples of comparative examples of the fourth embodiment.

### Example 4-1

Four Si substrates, each having a surface, as a principal surface, inclined at an off-angle of 2.0 degrees with respect to the (111) plane in the (011) plane direction, are prepared as the Si substrates 401. A nitride semiconductor layer 410 is formed on each of the Si substrates 401 by the above-described manufacturing method in the fourth embodiment so as to produce a sample of a nitride semiconductor layered body.

### Example 4-2

A nitride semiconductor layered body in Example 4-2 has the same structure as the structure of the nitride semiconductor layered body in Example 4-1 except that the Al composition ratio in the AlGaN buffer layer 406 is 20%.

### Example 4-3

A nitride semiconductor layered body in Example 4-3 has the same structure as the structure of the nitride semiconductor layered body in Example 4-1 except that the Al composition ratio in the AlGaN buffer layer 406 is 30%.

### Example 4-4

A nitride semiconductor layered body in Example 4-4 has the same structure as the structure of the nitride semiconductor layered body in Example 4-1 except that the Al composition ratio in the AlGaN buffer layer 406 is 50%.

### Example 4-5

A nitride semiconductor layered body in Example 4-5 has the same structure as the structure of the nitride semiconductor layered body in Example 4-1 except that the Al composition ratio in the AlGaN buffer layer 406 is 80%.

### Comparative Example 4-1

A nitride semiconductor layered body in Comparative example 4-1 has the same structure as the structure of the nitride semiconductor layered body in Example 4-1 except that the Al composition ratio in the AlGaN buffer layer 406 is 7.0%.

### Comparative Example 4-2

A nitride semiconductor layered body in Comparative example 4-2 has the same structure as the structure of the nitride semiconductor layered body in Example 4-1 except that the Al composition ratio in the AlGaN buffer layer 406 is 90%.

The surface state of the AlGaN barrier layer 408 in the sample of each of Example 4-1 to Example 4-3 and Comparative example 4-1 to Comparative example 4-3 was observed by SEM. Subsequently, an average number of pits on an area of 100 μm² basis of the surface of the AlGaN barrier layer 408 was calculated. The average numbers are shown in Table 4.

TABLE 4

| | Al composition ratio in | Number of |
|---|---|---|
| | AlGaN layer (%) | pits |
| Comparative example 4-1 | 7 | 8.1 |
| Example 4-1 | 10 | 0.4 |
| Example 4-2 | 20 | 0.5 |
| Example 4-3 | 30 | 0.8 |
| Example 4-4 | 50 | 1.8 |
| Example 4-5 | 80 | 2.1 |
| Comparative example 4-2 | 90 | 12.3 |

As shown in Table 4, the number of pits in the sample of each of Example 4-1 to Example 4-5 is 2.1 or less. In this regard, the number of pits in the sample of Comparative example 4-1 is 8.1, that is, about 4 times the number of pits of the sample of Example 4-1. The reason for this is considered as described below. In the case where the Al composition is small, the strain stress balance between the AlGaN layer and the Si substrate and other layers may be lost and pits are generated from dislocations easily.

Meanwhile, the number of pits in the sample of Comparative example 4-2 is 12.3, that is, about 6 times the number of pits of the sample of Example 4-5. The reason for this is considered as described below. In the case where the Al composition is too large as well, the strain stress balance between the AlGaN layer and the Si substrate and other layers may be lost and pits are generated from dislocations easily, as in the above-described case.

Therefore, the Al composition ratio in the AlGaN buffer layer 406 is preferably 10% or more and 80% or less. In the case where the Al composition ratio in the AlGaN buffer layer 406 is 10% or more, when the AlN buffer layer 406 is stacked on the AlGaN buffer layer 402, the reaction between Si and Ga is suppressed and warping of the entire substrate can be suppressed. Then, strain stress applied to the nitride semiconductor layer 410 by the warping is reduced and occurrences of dislocations and pits can be suppressed. Consequently, growth of hillock-like projections can be suppressed, the surface flatness of the nitride semiconductor layer 410 can be improved more reliably and, in addition, a high-performance nitride semiconductor layered body can be produced more reliably.

### Fifth Embodiment

A nitride semiconductor layered body according to a fifth embodiment of the present invention has the same structure as the structure of the nitride semiconductor layered body in the fourth embodiment except that a Si substrate having an off-angle of 2.0 degrees with respect to the (111) plane is used as the Si substrate 401. Regarding the nitride semiconductor layered body according to the fifth embodiment, the surface flatness on an area of 100 μm×100 μm basis was calculated by using AFM as in the first embodiment. The resulting surface flatness is shown in Table 5. Here, the surface flatness is a value determined by averaging the differences between the maximum height of projected portions and the minimum height of recessed portions on the surface of the above-described area.

TABLE 5

| Thickness of GaN (nm) | Surface flatness (nm) |
|---|---|
| 50 | 68.4 |
| 100 | 21.5 |
| 150 | 20.9 |
| 200 | 23.0 |
| 400 | 17.8 |
| 800 | 16.5 |

It is clear that in the case where the thickness of GaN is 100 nm or more, the surface flatness is improved to a great extent. The reason for this is considered to be that regarding growth of GaN, growth in the lateral direction is facilitated by an increase in thickness of GaN, and unevenness, e.g., hillocks, is suppressed.

### Sixth Embodiment

### Off-Angle Dependence and Rotation Axis Dependence of Off-Angle

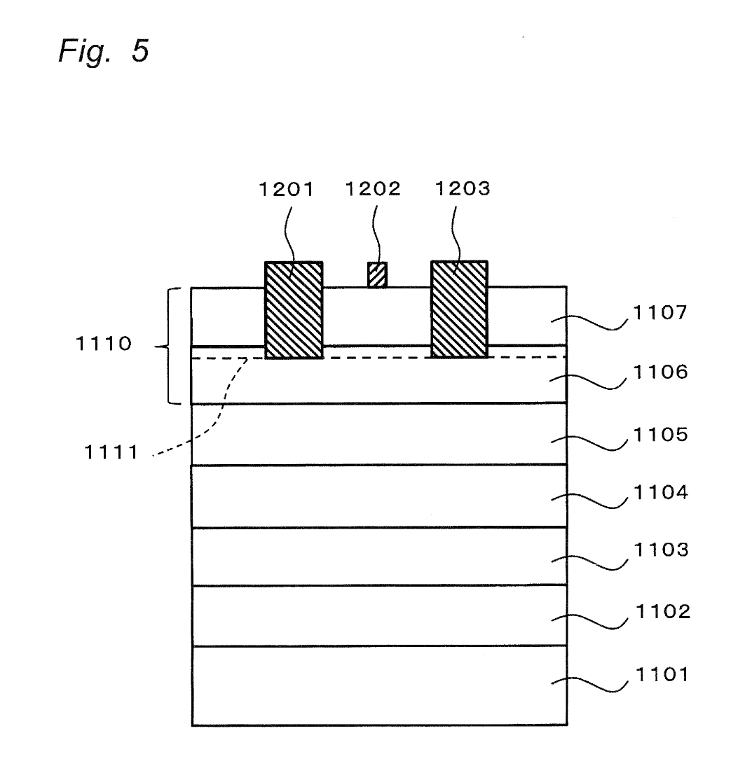

As shown in FIG. 5, a nitride semiconductor device according to a sixth embodiment includes a Si substrate 1101, an AlN buffer layer 1102 stacked on the Si substrate 1101, an AlGaN buffer layer 1103 stacked on the AlN buffer layer 1102, a 60-cycle AlN/AlGaN superlattice layer 1104 stacked on the AlGaN buffer layer 1103, an underlying GaN layer 1105 stacked on the superlattice layer 1104, a channel GaN layer 1106 stacked on the underlying GaN layer 1105, and a 2DEG barrier layer 1107 composed of Al_{0.17}Ga_{0.83} and stacked on the channel GaN layer 1106. The AlN buffer layer 1102, the AlGaN buffer layer 1103, the superlattice layer 1104, the underlying GaN layer 1105, the channel GaN layer 1106, and the 2DEG barrier layer 1107 constitute an example of the nitride semiconductor layer.

In this regard, the channel GaN layer 1106 and the 2DEG barrier layer 1107 constitute a GaN based layered body 1110 having a hetero junction. A 2DEG layer (two-dimensional electron gas layer) 1111 is generated at the interface between the channel GaN layer 1106 and the 2DEG barrier layer 1107.

Recesses, which reach the channel GaN layer 1106, are disposed in the GaN based layered body 1110, and a source electrode 1201 and a drain electrode 1203 serving as ohmic electrodes are disposed in the recesses. The source electrode 1201 and the drain electrode 1203 are, for example, Ti/Al/TiN electrodes in which a Ti layer, an AlN layer, and a TiN layer are stacked sequentially. Also, a gate electrode 1202 is disposed on the 2DEG barrier layer 1107. The gate electrode 1202 is, for example, a Schottky electrode, which has Schottky junction with the 2DEG barrier layer 1107, and is composed of, for example, TiN. In this regard, the gate electrode 1202 may be disposed on an insulating film so as to have an insulating gate electrode structure.

An interlayer insulating film, although not shown in the drawing, is disposed on the 2DEG barrier layer 1107, the source electrode 1201, the drain electrode 1203, and the gate electrode 1202, and a drain electrode pad, a source electrode pad, and a gate electrode pad, although not shown in the drawing, are disposed on the interlayer insulating film. In addition, the source electrode 1201, the drain electrode 1203, and the gate electrode 1202 are electrically connected to the drain electrode pad, the source electrode pad, and the gate electrode pad, respectively, through their respective through holes, although not shown in the drawing.

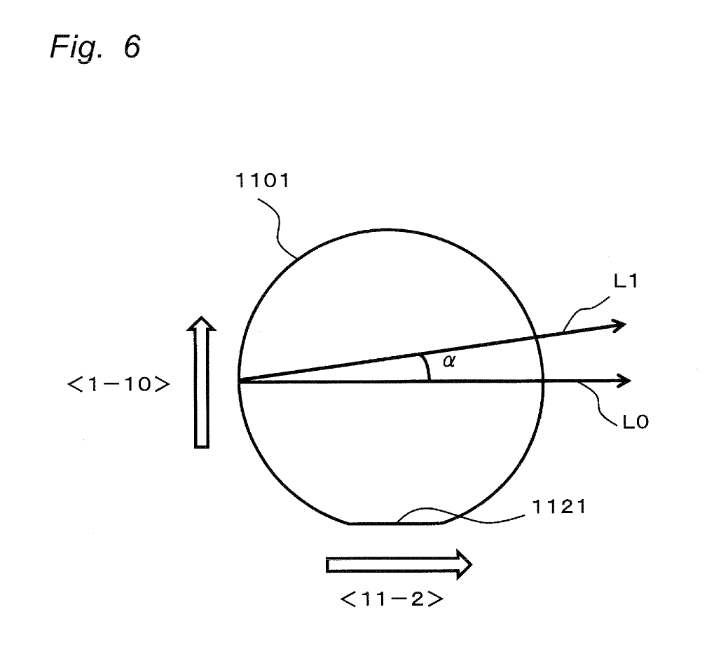

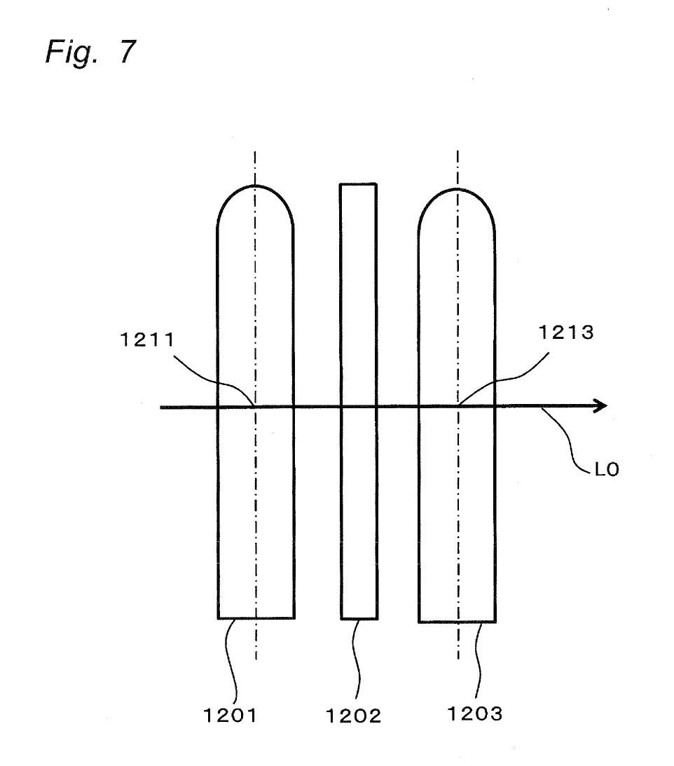

The Si substrate 1101 has an off-angle with respect to the (111) plane and, as shown in FIG. 6, an orientation flat portion 1121 (hereafter referred to as ori-fla portion) is disposed on the (1-10) plane. Then, as shown in FIG. 7, the above-described nitride semiconductor device is configured such that a straight line L0 passing through the barycenter 1211 of the source electrode 1201 and the barycenter 1213 of the drain electrode 1203 in the direction from the source electrode 1201 toward the drain electrode 1203 (hereafter referred to as electrode arrangement direction) becomes parallel to the ori-fla portion 1121. In other words, the source electrode 1201, the drain electrode 1203, and the gate electrode 1202 are arranged sequentially in the <1-12> direction parallel to the ori-fla portion 1121.

Also, the rotation axis of the above-described off-angle is a straight line L1 on the (111) plane of the Si substrate 1101 and in the direction at an angle α with respect to the straight line L0.

Here, the relationship between the angle α, which is formed by the straight line L1 serving as the rotation axis of the off-angle α nd the straight line L0 in the electrode arrangement direction, and the mobility of electrons and the value of current collapse in the vicinity of the 2DEG layer 1111 will be described.

In this regard, seven samples,
Nitride semiconductor device (HEMT) denoted as Sample 1-1 in which Si (111) having an off-angle of 2 degrees was used as the substrate, where the rotation axis of the off-angle was the straight line L1 at an angle α of 0 degrees (parallel to L0) with respect to the straight line L0 in the electrode arrangement direction,
HEMT denoted as Sample 1-2 in which Si (111) having an off-angle of 2 degrees was used as the Si substrate 1101, where the rotation axis of the off-angle was the straight line L1 at an angle α of 10 degrees with respect to the straight line L0 in the electrode arrangement direction,
HEMT denoted as Sample 1-3 in which Si (111) having an off-angle of 2 degrees was used as the Si substrate 1101, where the rotation axis of the off-angle was the straight line L1 at an angle α of 20 degrees with respect to the straight line L0 in the electrode arrangement direction,
HEMT denoted as Sample 1-4 in which Si (111) having an off-angle of 2 degrees was used as the Si substrate 1101, where the rotation axis of the off-angle was the straight line L1 at an angle α of 25 degrees with respect to the straight line L0 in the electrode arrangement direction,
HEMT denoted as Sample 1-5 in which Si (111) having an off-angle of 2 degrees was used as the Si substrate 1101, where the rotation axis of the off-angle was the straight line L1 at an angle α of 30 degrees with respect to the straight line L0 in the electrode arrangement direction,
HEMT denoted as Sample 1-6 in which Si (111) having an off-angle of 2 degrees was used as the Si substrate 1101, where the rotation axis of the off-angle was the straight line L1 at an angle α of 35 degrees with respect to the straight line L0 in the electrode arrangement direction, and
HEMT denoted as Sample 1-7 in which Si (111) having an off-angle of 2 degrees was used as the Si substrate 1101, where the rotation axis of the off-angle was the straight line L1 at an angle α of 40 degrees with respect to the straight line L0 in the electrode arrangement direction, were prepared as samples.

In the sample, a nitride semiconductor layered substrate (nitride semiconductor epitaxial substrate), in which the AlN buffer layer 1102 having a layer thickness of 40 nm, the AlGaN buffer layer 1103, the 60-cycle superlattice layer 1104 of AlN/Al_{0.15}Ga_{0.85}N having a layer thickness of 3.5 nm/23 nm, the underlying GaN layer 1105 having a layer thickness of 600 nm, the channel GaN layer 1106 having a layer thickness of 600 nm, and the 2DEG barrier layer 1107 of Al_{0.17}Ga_{0.83} having a layer thickness of 32 nm were stacked sequentially on the Si substrate 1101 of 675 μm and 6 inches, was used. In every sample, the same electrode (source electrode 1201, drain electrode 1203, and gate electrode 1202) was used and the same arrangement was employed. Also, as shown in FIG. 6, the straight line L0 in the electrode arrangement direction and the straight line L1 in the direction at an angle α with respect to the straight line L0 and on the (111) plane of the Si substrate 1101 are arranged such that these straight lines L0 and L1 intersect with each other on the outer perimeter of the Si substrate 1101.

The above-described samples were subjected to a hall effect measurement in the vicinity of the electrodes 1201, 1202, and 1203.

As a result, the middle values (medians) of the mobility were

1,815 cm2/V·sec as for Sample 1-1,

1,783 cm2/V·sec as for Sample 1-2,

1,762 cm2/V·sec as for Sample 1-3,

1,748 cm2/V·sec as for Sample 1-4,

1,726 cm2/V·sec as for Sample 1-5,

1,658 cm2/V·sec as for Sample 1-6, and

1,580 cm2/V·sec as for Sample 1-7.

Also, the middle values (medians) of the values of current collapse, which were rates of change in on-resistance, were

1.05 as for Sample 1-1,

1.09 as for Sample 1-2,

1.11 as for Sample 1-3,

1.10 as for Sample 1-4,

1.14 as for Sample 1-5,

1.28 as for Sample 1-6, and

1.32 as for Sample 1-7.

As is clear from the above-described results, in the case where the angle α formed by the straight line L0 and the straight line L1 was more than 30 degrees, the mobility in the vicinity of the 2DEG layer 1111 was reduced to a great extent and the value of current collapse increased to a great extent.

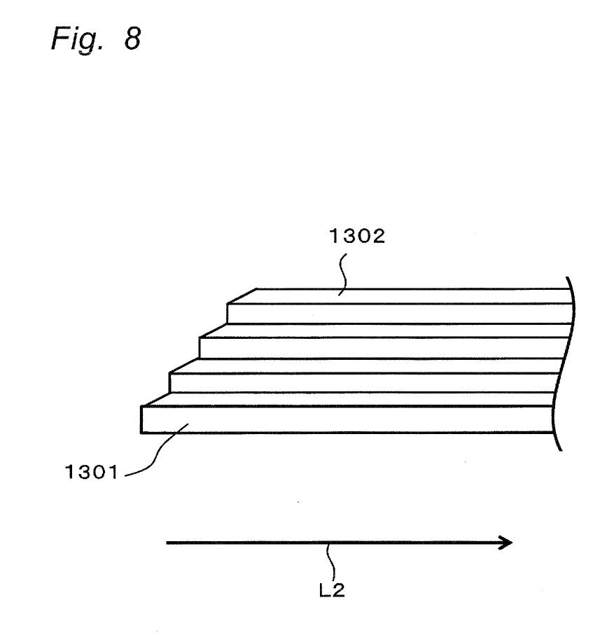

As shown in FIG. 8, the border between a step 1301 and a terrace 1302 in a Si atomic layer extends in the direction substantially parallel to the straight line L1 that is the rotation axis of the off-angle. The extension direction of the border between the step and the terrace hardly changes even in the vicinity of the 2DEG layer 1111 produced by growing a crystal of nitride semiconductor on the Si substrate 1101. Consequently, as the above-described angle α comes close to 0 degrees, the straight line L0 in the electrode arrangement direction and the straight line L2 indicating the extension direction of the border between the step and the terrace come close to parallel to each other, and the “direction of movement of carriers when a voltage is applied”, which is considered to be in accordance with the electrode arrangement direction, and the extension direction of the border between the step and the terrace come close to parallel to each other. As a result, the mobility of electrons (carriers) when a voltage is applied is improved and a depletion region is replenished with electrons easily. That is, the mobility of electrons generated in the vicinity of the 2DEG layer 1111 can be improved by specifying the rotation axis of the off-angle α s the straight line L1 on the (111) plane of the Si substrate 1101 and in the direction at an angle α of 0 degrees or more and 30 degrees or less with respect to the straight line L0 in the electrode arrangement direction. Therefore, it is possible to suppress an increase in on-resistance of the nitride semiconductor device and reduce current collapse.

On the other hand, in the case where the rotation axis of the off-angle is specified as a straight line in the direction at an angle α of more than 30 degrees with respect to the straight line L0 in the electrode arrangement direction, the “direction of movement of carriers when a voltage is applied”, which is considered to be in accordance with the electrode arrangement direction, and the extension direction of the border between the step and the terrace are out of parallel to each other. As a result, the mobility of carriers when a voltage is applied is reduced, a depletion region is not replenished with electrons easily, on-resistance of the nitride semiconductor device increases, and current collapse increases.

Therefore, the rotation axis of the off-angle of the Si substrate 1101 is specified as the straight line L1 on the (111) plane of the Si substrate 1101 and in the direction at an angle α of 0 degrees or more and 30 degrees or less with respect to the straight line L0 in the electrode arrangement direction.

In this regard, the straight line L1 only has to be a straight line at an angle of 0 degrees or more and 30 degrees or less with respect to the straight line L0 and can be set at any position on the Si substrate 1101.

Also, the off-angle is set at an angle of 0 degrees or more and 4.0 degrees or less with respect to the (111) plane.

This is because in the case where the Si substrate 1101 of 675 μm and 6 inches is used, if the off-angle is more than 4.0 degrees, warp of the Si substrate 1101 (warp with the projection side down where the nitride semiconductor layer side faces upward) at room temperature is large (120 μm or more) and it is difficult to perform processing.

Meanwhile, in the case where the off-angle is 4.0 degrees or less, warp of the Si substrate 1101 is 100 μm or less and it is possible to perform processing. In particular, in the case where the off-angle is 2.7 degrees or less, warp of the Si substrate 1101 is 70 μm or less and it is easy to perform processing. Consequently, the off-angle is preferably 2.7 degrees or less and more preferably 1.7 degrees or less.

On the other hand, if the off-angle is too small (excessively approach 0 degrees), even in the case where the off-angle is slightly changed, differences are caused in the distance, the direction, and the like of the step 1301, and a predetermined surface state of the substrate 1101 is not obtained. Consequently, the off-angle is preferably 0.1 degrees or more and more preferably 0.3 degrees or more.

### Seventh Embodiment

### AlN Thickness Dependence of AlN Layer/Si Substrate

A nitride semiconductor device, although not shown in the drawing, according to a seventh embodiment is the same as the nitride semiconductor device according to the sixth embodiment except that the AlN buffer layer 1102 is configured to have a layer thickness of 30 nm or more and 400 nm or less. In this regard, the same configuration portions as those in the sixth embodiment are indicated by the same reference numerals as the reference numerals set forth above and the explanations in the sixth embodiment are quoted.

To begin with, the layer thickness of the AlN buffer layer 1102 and a difference between the maximum height and the minimum height of the surface of the AlN buffer layer 1102 will be described.

Seven samples,
A nitride semiconductor layered substrate (nitride semiconductor epitaxial substrate) of Sample 2-1 produced by specifying the layer thickness of the AlN buffer layer 1102 as 20 nm,
A nitride semiconductor layered substrate of Sample 2-2 produced by specifying the layer thickness of the AlN buffer layer 1102 as 30 nm,
A nitride semiconductor layered substrate of Sample 2-3 produced by specifying the layer thickness of the AlN buffer layer 1102 as 50 nm,
A nitride semiconductor layered substrate of Sample 2-4 produced by specifying the layer thickness of the AlN buffer layer 1102 as 180 nm,
A nitride semiconductor layered substrate of Sample 2-5 produced by specifying the layer thickness of the AlN buffer layer 1102 as 400 nm,
A nitride semiconductor layered substrate of Sample 2-6 produced by specifying the layer thickness of the AlN buffer layer 1102 as 450 nm, and
A nitride semiconductor layered substrate of Sample 2-7 produced by specifying the layer thickness of the AlN buffer layer 1102 as 500 nm, were prepared as the samples.

Regarding the sample, a nitride semiconductor epitaxial substrate, in which the AlN buffer layer 1102, the AlGaN buffer layer 1103, the 60-cycle superlattice layer 1104 of AlN/Al_{0.15}Ga_{0.85}N having a layer thickness of 3.5 nm/23 nm, the underlying GaN layer 1105 having a layer thickness of 600 nm, the channel GaN layer 1106 having a layer thickness of 600 nm, and the 2DEG barrier layer 1107 of Al_{0.17}Ga_{0.83} having a layer thickness of 32 nm were stacked sequentially on the Si substrate 1101 of 675 μm and 6 inches, was used.

Regarding the surface of the AlN buffer layer 1102 of each of the nitride semiconductor layered substrates of the samples, a difference between the maximum height and the minimum height in an area of 5 μm×5 μl was evaluated by using AFM (atomic force microscope).

The results were
113 nm as for Sample 2-1,
48 nm as for Sample 2-2,
41 nm as for Sample 2-3,
31 nm as for Sample 2-4,
36 nm as for Sample 2-5,
83 nm as for Sample 2-6, and
121 nm as for Sample 2-7.

As is clear from the above-described results, in the case where the layer thickness of the AlN buffer layer 1102 was less than 30 nm or more than 400 nm, the difference between the maximum height and the minimum height of the surface of the AlN buffer layer 1102 for growing the nitride semiconductor layer became excessively large.

Therefore, it is assumed that if the difference between the maximum height and the minimum height of the surface of the AlN buffer layer 1102 is excessively large, even in the case where the rotation axis of the off-angle is specified as a straight line L1 in the direction at an angle α of more than 30 degrees with respect to the straight line L0 in the electrode arrangement direction and on the (111) plane of the Si substrate 1101, the “direction of movement of carriers when a voltage is applied”, which is considered to be in accordance with the electrode arrangement direction, and the extension direction of the border between the step and the terrace are out of parallel to each other and the mobility of carriers when a voltage is applied is reduced. Consequently, the layer thickness of the AlN buffer layer 1102 is specified as 30 nm or more and 400 nm or less. Reduction in the mobility of carriers due to the surface shape of the AlN buffer layer 1102 when a voltage is applied can be suppressed by specifying the layer thickness of the AlN buffer layer 1102 as 30 nm or more and 400 nm or less. As a result, an increase in on-resistance of the nitride semiconductor device is suppressed, and current collapse can be reduced.

### Eighth Embodiment

### Crystal Dependence of AlN Layer/Si Substrate

A nitride semiconductor device, although not shown in the drawing, according to an eighth embodiment is the same as the nitride semiconductor device according to the sixth embodiment except that the AlN buffer layer 1102 is configured to exhibit a half-width of a rocking curve based on X-ray diffraction of the (0002) plane of 2,500 arcsec or less. In this regard, the same configuration portions as those in the sixth embodiment are indicated by the same reference numerals as the reference numerals set forth above and the explanations in the sixth embodiment are quoted.

In the case where the half-width of a rocking curve based on X-ray diffraction of the (0002) plane of the AlN buffer layer 1102 is 2,500 arcsec or less, the crystallinity is good and occurrences of dislocations are suppressed (dislocations are relatively reduced). Therefore, it is considered that the reaction between Si and Ga can be suppressed when the AlGaN buffer layer 1103 is stacked. As a result, reduction in the mobility of carrier due to dislocations can be suppressed and, thereby, it is possible to suppress an increase in on-resistance of the nitride semiconductor device and reduce current collapse.

### Ninth Embodiment

### Al Composition Dependence of AlGaN Layer/AlN Layer/Si Substrate

A nitride semiconductor device, although not shown in the drawing, according to a ninth embodiment is the same as the nitride semiconductor device according to the sixth embodiment except that an AlGaN buffer layer 1103 having an Al composition of 10% or more and 80% or less and an AlN/AlGaN superlattice layer 1104 are disposed on the AlN buffer layer 1102 and an underlying GaN layer 1105 having a layer thickness of 100 nm or more is stacked on the superlattice layer 1104. In this regard, the same configuration portions as those in the sixth embodiment are indicated by the same reference numerals as the reference numerals set forth above and the explanations in the sixth embodiment are quoted.

According to the nitride semiconductor device of the ninth embodiment, warping of the entire nitride semiconductor layered substrate can be suppressed, strain stress applied to the nitride semiconductor layer, that is, the AlN buffer layer 1102, the AlGaN buffer layer 1103, the superlattice layer 1104, the underlying GaN layer 1105, the channel GaN layer 1106, and the 2DEG barrier layer 1107 is reduced, and occurrences of dislocations can be suppressed. As a result, reduction in the mobility of carriers due to dislocations can be suppressed and, thereby, it is possible to suppress an increase in on-resistance of the nitride semiconductor device and reduce current collapse.

### Tenth Embodiment

A nitride semiconductor device, although not shown in the drawing, according to a tenth embodiment is the same as the nitride semiconductor device according to the sixth embodiment except that the surface of the Si substrate 1101 has unevenness such that the proportion of the surface inclined at an off-angle of 0 degrees or more and 4.0 degrees or less with respect to the (111) plane is 30% or more of the surface of the Si substrate 1101, where the rotation axis is the straight line L1 in the direction at an angle α of 0 degrees or more and 30 degrees or less with respect to the straight line L0 in the electrode arrangement direction. In this regard, the same configuration portions as those in the sixth embodiment are indicated by the same reference numerals as the reference numerals set forth above and the explanations in the sixth embodiment are quoted.

An increase in on-resistance of the nitride semiconductor device is suppressed reliably and current collapse can be reduced by disposing unevenness on the surface of the Si substrate 1101 such that the proportion of the surface inclined at an off-angle of 0 degrees or more and 4.0 degrees or less with respect to the (111) plane is 30% or more of the surface of the Si substrate 1101, where the rotation axis is the straight line L1 in the direction at an angle α of 0 degrees or more and 30 degrees or less with respect to the straight line L0 in the electrode arrangement direction.

In this regard, in the second to fourth embodiments, the principal surfaces of the Si substrates 201, 301, and 401 are surfaces inclined at an off-angle of 2.0 degrees with respect to the (111) plane in the (011) plane direction but are not limited to this. The principal surface of the Si substrate only has to be a surface inclined at an off-angle of 0.8 degrees or more and 2.7 degrees or less with respect to the (111) plane in the (011) plane direction.

Also, in the first, third, and fourth embodiments, the thicknesses of the AlN buffer layers 102, 302, and 402 are 180 nm but are not limited to this. The thickness of the AlN buffer layer only has to be 50 nm or more and 400 nm or less.

Also, in the first, second, and fourth embodiments, the AlN buffer layers 102, 202, and 402 are AlN buffer layers exhibiting a half-width of a rocking curve based on X-ray diffraction of the (0002) plane of 1,900 arcsec but are not limited to this. The half-width of a rocking curve based on X-ray diffraction of the (0002) plane of the AlN buffer layer only has to be 2,500 arcsec or less.

Also, in the first to third embodiments, the thicknesses of the GaN layers 107, 207, and 307 are 1,000 nm and in the fourth embodiment, the thickness of the GaN layer 407 is 200 nm, but the thicknesses are not limited to these. The thickness of the GaN layer only has to be 100 nm or more.

Also, in the first to third embodiments, each of the surfaces of the Si substrates 101, 201, 301, and 401 is roughened such that the principal surface is present in a region constituting 30% or more of the region of the surface but the proportion is not limited to this. The surface may be roughened such that the principal surface of the Si substrate is present in a region constituting 30% or more of the surface of the Si substrate. Meanwhile, the surfaces of the Si substrates 101 201, 301, and 401 are not necessarily roughened.

Also, in the first to fifth embodiments, crystals of the individual layers are grown by using the MOCVD method including an MOCVD apparatus. The method is not limited to this, and a HVPE (hydride vapor phase epitaxial) method, a MBE (molecular beam epitaxial) method, and the like may be employed, and the MOCVD method, the HYPE method, the MBE method, and the like may be combined. In addition, the growth conditions of the individual layers may be set appropriately in accordance with the configuration and the like of the semiconductor device to be produced by using the nitride semiconductor layered body.

Also, in the sixth to tenth embodiments, the GaN based layered body 1110 is composed of the channel GaN layer 1106 and the 2DEG barrier layer 1107 of Al_{0.17}Ga_{0.83} stacked on the channel GaN layer 1106 but is not limited to this. The GaN based layered body only has to be a layered body in which GaN based semiconductor layers represented by InₓAl_{y}Ga_{1-x-y}N (0≦x≦1, 0≦y≦1, and 0≦x+y≦1) are stacked. For example, the GaN based layered body may contain InGaN that is a mixed crystal of GaN and indium nitride (InN), AlInGaN that is a mixed crystal of GaN, AlN, and InN, or the like in addition to GaN and AlGaN.

Also, in the sixth to tenth embodiments, recesses, which reach the channel GaN layer 1106, are disposed in the 2DEG barrier layer 1107, and the source electrode 1201 and the drain electrode 1203 serving as ohmic electrodes are disposed in the recesses but the configuration is not limited to this. For example, the drain electrode and the source electrode may be made as ohmic electrodes by forming the source electrode and the drain electrode on the 2DEG barrier layer on the channel GaN layer without forming the above-described recesses, and decreasing the layer thickness of the 2DEG barrier layer.

The above-described nitride semiconductor device may be, for example, HEMT (high electron mobility transistor), MISFET (metal insulator semiconductor field effect transistor), a junction FET, LED (light-emitting diode), a semiconductor laser, or the like.

As a matter of course, the electrode serves as a drain electrode, a source electrode, a gate electrode, an emitter electrode, a collector electrode, a base electrode, an anode, a cathode, or the like in accordance with the type of the nitride semiconductor device.

Also, in the sixth to tenth embodiments, the ori-fla portion 1121 of the Si substrate 1101 is disposed parallel to the <11-2> direction but is not limited to this. For example, the ori-fla portion may be disposed parallel to the <1-10> direction or be disposed in other directions.

Also, in the sixth to tenth embodiments, the AlN buffer layer 1102 is used as the barrier layer but, for example, a layer composed of p-GaN, p-AlGaN, or the like can be used instead of the AlN buffer layer 1102. Also, the Al composition of the AlGaN buffer layer 1103 serving as the buffer layer may be changed in the layer thickness direction, as describe in PTL 1.

In this regard, the components described in the first to tenth embodiments and the modified examples may be combined appropriately, or be selected, substituted, or removed appropriately, as a matter of course.

The present invention and the embodiments are summarized as described below.

The nitride semiconductor layered bodies according to the present invention include

the Si substrates 101, 201, 301, 401, and 1101 having a surface, as a principal surface, inclined at an off-angle of 0 degrees or more and 4.0 degrees or less with respect to the (111) plane, and

the nitride semiconductor layers 110, 210, 310, 410, 1102, 1103, 1104, 1105, 1106, and 1107 disposed on the Si substrates 101, 201, 301, 401, and 1101.

According to the nitride semiconductor layered bodies having the above-described configurations, the Si substrates 101, 201, 301, 401, and 1101 have the surfaces inclined at an off-angle of 0 degrees or more and 4.0 degrees or less with respect to the (111) plane as the principal surfaces. Therefore, the mobility of electrons generated in the vicinity of the 2DEG layer 1111 can be improved by including such nitride semiconductor layered bodies and the source electrode and the drain electrode, which are disposed on the nitride semiconductor layers 1102, 1103, 1104, 1105, 1106, and 1107 and which are arranged at a predetermined distance from each other, wherein each of the straight lines L1 on the Si substrates 101, 201, 301, 401, and 1101 in the direction at an angle of 0 degrees or more and 30 degrees or less with respect to the straight line L0 in the direction from the barycenter of the source electrode toward the barycenter of the drain electrode is specified as the rotation axis of the above-described off-angle. Therefore, it is possible to suppress an increase in on-resistance of the nitride semiconductor device and reduce current collapse.

Meanwhile, the nitride semiconductor layered body in related art includes an AlN layer, an AlGaN layer, which is disposed on the AlN layer and which has an Al composition ratio of 30% or more and 60% or less, and a GaN layer disposed on the AlGaN layer.

However, the present inventors were faced with a problem that when the AlN layer was grown on the Si substrate, unevenness resulting from hillocks or step bunching was developed on the AlN layer surface or the AlGaN layer surface on the AlN layer easily.

Then, the present inventors performed research particularly on a problem that hillock-like projections were generated on the AlGaN layer surface. As a result, the following was estimated. That is, when the off-angle of the principal surface of the Si substrate was small, the number of steps at an atomic level on the substrate surface was reduced. Atoms of Al or the like stopped at some midpoint in surface migration on a terrace, nucleation started therefrom, and a crystal nucleus was developed in a manner different from regular step flow growth. It was considered that the resulting crystal nucleus was the cause of generation of a hillock-like projection.

Meanwhile, when a nitride semiconductor layered body including an epitaxial film having unevenness including hillock-like projections was produced, dislocation of an antiphase boundary portion at an interface between a “crystal constituting a hillock-like projection” and a “crystal in a step-flow growth area” and a difference in process, e.g., photolithography, due to height differences of the surface occurred. It was considered that these led to leakage, in-plane unevenness, and the like, so as to degrade the performance of the nitride semiconductor layered body.

Accordingly, another issue of the present invention is to provide a high-performance nitride semiconductor layered body, in which the surface flatness of a nitride semiconductor layer can be improved, and a method for manufacturing the same.

In order to solve the above-described issue, in a nitride semiconductor layered body according to an embodiment,

the off-angle of the principal surface of the Si substrate is 0.8 degrees or more and 2.7 degrees or less with respect to the (111) plane.

According to the nitride semiconductor layered body of the above-described embodiment, the principal surface of each of the Si substrates 101, 201, 301, and 401 has an off-angle of 0.8 degrees or more and 2.7 degrees or less with respect to the (111) plane. Consequently, the terrace width of the growth surface is reduced compared with the case where the off-angle is less than 0.8 degrees with respect to the (111) plane. At this time, even in the case where a growth temperature is relatively low, the distance of migration of a precursor, which is an atom or a molecule before growth, is small. Therefore, step-flow growth occurs easily, the tendency of the precursor to stop at some midpoint in a terrace and start nucleation in a crystal orientation different from the orientation of the step flow is reduced. As a result, growth of a hillock-like projection is suppressed so as to reduce surface unevenness.

Also, the terrace width does not excessively decreases compared with the case where the off-angle is more than 2.7 degrees with respect to the (111) plane, and it is possible to prevent irregular growth such as occupation of a position, which should be the position of a group V site, by a group III atom because of excessive proceeding of step-flow growth and loss of the atomic balance between step-flow growth and release from the surface. As a result, growth of a hillock-like projection can be suppressed and surface unevenness can be reduced.

Meanwhile, in the case where a nitride semiconductor layered body including an epitaxial film having reduced unevenness including hillock-like projections is produced, occurrences of dislocation of an antiphase boundary portion at an interface between a “crystal constituting a hillock-like projection” and a “crystal in a step-flow growth area” and a difference in process, e.g., photolithography, due to height differences of the surface can be prevented. Consequently, leakage, in-plane unevenness, and the like can be prevented.

Therefore, the surface flatness of each of the nitride semiconductor layers 110, 210, 310, and 410 can be improved and a high-performance nitride semiconductor layered body can be produced.

Also, in nitride semiconductor layered bodies according to an embodiment, the nitride semiconductor layers include AlN layers 102, 202, 302, and 402 disposed on the principal surfaces of the Si substrates 101, 201, 301, and 401, respectively, and

the thicknesses of the AlN layers 102, 202, 302, and 402 are 50 nm or more and 400 nm or less.

According to the above-described embodiment, the thicknesses of the AlN layers 102, 202, 302, and 402 are 50 nm or more. Therefore, the AlN layers 102, 202, 302, and 402 function as the cover layer sufficiently. Consequently, in the case where the GaN layers 107, 207, 307, and 407 are stacked on the AlN layers 102, 202, 302, and 402, respectively, the reaction between Si and Ga can be suppressed, growth of hillock-like projections can be suppressed and, in addition, occurrences of threading dislocations, which cause generation of pits, can be reduced.

Also, the thicknesses of the AlN layers 102, 202, 302, and 402 are 400 nm or less. Therefore, warping of the Si substrates 101, 201, 301, and 401 due to a difference in lattice constant between Si and AlN is suppressed, application of strain stress to the AlN layers 102, 202, 302, and 402 can be suppressed, and occurrences of pits can be reduced.

Also, in nitride semiconductor layered bodies according to an embodiment,

the half-width of a rocking curve based on X-ray diffraction of the (0002) plane of each of the AlN layers 102, 202, 302, and 402 is 2,500 arcsec or less.

According to the above-described embodiment, the half-width of a rocking curve based on X-ray diffraction of the (0002) plane of each of the AlN layers 102, 202, 302, and 402 is 2,500 arcsec or less. Therefore, occurrences of dislocations are reduced, and when the GaN layers 107, 207, 307, and 407 are stacked on the AlN layers 102, 202, 302, and 402, respectively, the reaction between Si and Ga can be suppressed. In addition, the crystallinity of the AlN layers 102, 202, 302, and 402 is good, occurrences of dislocations are reduced, and generation of pits can be reduced. Consequently, the surface flatness of the nitride semiconductor layers 110, 210, 310, and 410 can be improved more reliably, and high-performance nitride semiconductor layered bodies can be produced more reliably.

Also, in nitride semiconductor layered bodies according to an embodiment,

at least one AlGaN layer is disposed on the AlN layer, for example, the AlGaN layers 106, 206, 306, and 406 are disposed on the AlN layers 102, 202, 302, and 402, respectively,

a GaN layer is disposed on the AlGaN layer, for example, the GaN layers 107, 207, 307, and 407 are disposed on the AlGaN layers 106, 206, 306, and 406, respectively,

the Al composition ratio in each of the AlGaN layers 106, 206, 306, and 406 is 10% or more and 80% or less, and the thickness of each of the GaN layers 107, 207, 307, and 407 is 100 nm or more.

According to the above-described embodiment, the Al composition ratio of each of the AlGaN layers 106, 206, 306, and 406 is 10% or more and 80% or less, and the thickness of each of the GaN layers 107, 207, 307, and 407 is 100 nm or more. Therefore, when the AlGaN layers 106, 206, 306, and 406 are stacked on the AlN layers 102, 202, 302, and 402, respectively, the reaction between Si and Ga is suppressed and warping of the entire substrate can be suppressed. Then, strain stress applied to each of the nitride semiconductor layers 110, 210, 310, and 410 by the warping is reduced and occurrences of dislocations and pits can be suppressed. Consequently, growth of hillock-like projections can be suppressed, the surface flatness of each of the nitride semiconductor layers 110, 210, 310, and 410 can be improved more reliably, and a high-performance nitride semiconductor layered bodies can be produced more reliably.

Also, in nitride semiconductor layered bodies according to an embodiment,

the surfaces of the Si substrates 101, 201, 301, and 401 are roughened such that the principal surfaces are present in regions constituting 30% of the above-described surface regions.

According to the above-described embodiment, the surfaces of the Si substrates 101, 201, 301, and 401 are roughened such that the principal surfaces are present in regions constituting 30% of the above-described surface regions. Consequently, in the above-described regions, the terrace width of the growth surface decreases, warping of each of the Si substrates 101, 201, 301, and 401 due to a difference in lattice constant between Si and AlN is suppressed more reliably, application of strain stress to each of the AlN layers 102, 202, 302, and 402 can be suppressed, and generation of pits can be reduced more reliably. Therefore, growth of hillock-like projections can be suppressed, the surface flatness of each of the nitride semiconductor layers 110, 210, 310, and 410 can be improved more reliably, and high-performance nitride semiconductor layered bodies can be produced more reliably.

Also, the method for manufacturing a nitride semiconductor layered body, according to the present invention, includes the step of

forming a nitride semiconductor layer such as nitride semiconductor layers 110, 210, 310, and 410 on a Si substrate such, as Si substrates 101, 201, 301, and 401 through epitaxial growth,

wherein the principal surface of the Si substrate such as Si substrates 101, 201, 301, and 401 has an off-angle of 0.8 degrees or more and 2.7 degrees or less with respect to the (111) plane.

According to the above-described configuration, the nitride semiconductor layers 110, 210, 310, and 410 are formed on the Si substrates 101, 201, 301, and 401, respectively, through epitaxial growth, and the principal surfaces of the Si substrates 101, 201, 301, and 401 have off-angles of 0.8 degrees or more and 2.7 degrees or less with respect to the (111) plane. Consequently, the terrace width of the growth surface is reduced compared with the case where the off-angle is less than 0.8 degrees with respect to the (111) plane. At this time, even in the case where a growth temperature is relatively low, the distance of migration of a precursor, which is an atom or a molecule before growth, is small. Therefore, step-flow growth occurs easily, the tendency of the precursor to stop at some midpoint in a terrace and start nucleation in a crystal orientation different from the orientation of the step flow is reduced. As a result, growth of a hillock-like projection is suppressed so as to reduce surface unevenness.

Also, the terrace width does not excessively decreases compared with the case where the off-angle is more than 2.7 degrees with respect to the (111) plane, and it is possible to prevent irregular growth such as occupation of a position, which should be the position of a group V site, by a group III atom because of excessive proceeding of step-flow growth and loss of the atomic balance between step-flow growth and release from the surface. As a result, growth of a hillock-like projection can be suppressed and surface unevenness can be reduced.

Meanwhile, in the case where a nitride semiconductor layered body including an epitaxial film having reduced unevenness including hillock-like projections is produced, occurrences of dislocation of an antiphase boundary portion at an interface between a “crystal constituting a hillock-like projection” and a “crystal in a step-flow growth area” and a difference in process, e.g., photolithography, due to height differences of the surface can be prevented. Consequently, leakage, in-plane unevenness, and the like can be prevented.

Therefore, the surface flatness of each of the nitride semiconductor layers 110, 210, 310, and 410 can be improved and a high-performance nitride semiconductor layered body can be produced.

The nitride semiconductor device according to the present invention includes

the above-described nitride semiconductor layered body and

the source electrode 1201 and the drain electrode 1203 disposed on the nitride semiconductor layers 1102, 1103, 1104, 1105, 1106, and 1107 and arranged at a predetermined distance from each other,

wherein the straight line L1 on the Si substrate 1101 in the direction at an angle of 0 degrees or more and 30 degrees or less with respect to the straight line L0 in the direction from the barycenter of the source electrode 1201 toward the barycenter of the drain electrode 1203 is specified as the rotation axis of the off-angle.

According to the nitride semiconductor device having the above-described configuration, the mobility of electrons generated in the vicinity of the 2DEG layer 1111 can be improved. Therefore, it is possible to suppress an increase in on-resistance of the nitride semiconductor device and reduce current collapse.

In a nitride semiconductor device according to an embodiment,

the AlN layer 1102, which serves as the nitride semiconductor layer such as the nitride semiconductor layers 1102, 1103, 1104, 1105, 1106, and 1107 and which has a layer thickness of 30 nm or more and 400 nm or less, is stacked on the Si substrate 101.

According to the above-described embodiment, reduction in the mobility of electrons due to the surface shape of the AlN layer 1102 when a voltage is applied can be suppressed. As a result, an increase in on-resistance of the nitride semiconductor device is suppressed, and current collapse can be reduced.

In the nitride semiconductor device according to an embodiment,

the half-width of a rocking curve based on X-ray diffraction of the (0002) plane of the AlN layer 1102 is 2,500 arcsec or less.

According to the above-described embodiment, the crystallinity is good and occurrences of dislocations are suppressed (dislocations are relatively reduced). Therefore, it is considered that the reaction between Si and Ga can be suppressed when the AlGaN layer 1103 is stacked. As a result, reduction in the mobility of electrons due to dislocation can be suppressed and, thereby, it is possible to suppress an increase in on-resistance of the nitride semiconductor device and reduce current collapse.

In the nitride semiconductor device according to an embodiment,

at least one AlGaN layer such as the AlGaN layers 1103 and 1104, which serves as the nitride semiconductor layer such as the nitride semiconductor layers 1102, 1103, 1104, 1105, 1106, and 1107 and which has an Al composition of 10% or more and 80% or less, is stacked on the AlN layer 102, and

the GaN layer 1105, which serves as the nitride semiconductor layer such as the nitride semiconductor layers 1102, 1103, 1104, 1105, 1106, and 1107 and which has a layer thickness of 100 nm or more, is stacked on the AlGaN layer 1104.

According to the above-described embodiment, warping of the entire nitride semiconductor layered substrate can be suppressed, strain stress applied to the nitride semiconductor layers 1102, 1103, 1104, 1105, 1106, and 1107 is reduced, and occurrences of dislocations can be suppressed. As a result, reduction in the mobility of electrons due to dislocations can be suppressed and, thereby, it is possible to suppress an increase in on-resistance of the nitride semiconductor device and reduce current collapse.

In the nitride semiconductor device according to an embodiment,

the surface of the Si substrate 1101 has unevenness such that the proportion of the surface inclined at an off-angle of 0 degrees or more and 4.0 degrees or less with respect to the (111) plane is 30% or more of the surface of the Si substrate 1101.

According to the above-described embodiment, an increase in on-resistance of the nitride semiconductor device is suppressed reliably and current collapse can be reduced.

### REFERENCE SIGNS LIST

101, 201, 301, 401, 1101 Si substrate
102, 202, 302, 402, 1102 AlN buffer layer
103, 203, 303, 403 AlGaN-1 layer
104, 204, 304, 404 AlGaN-2 layer
105, 205, 305, 405 AlGaN-3 layer
106, 206, 306, 406, 1103 AlGaN buffer layer
107, 207, 307, 407 GaN layer
108, 208, 308, 408 AlGaN barrier layer
1104 superlattice layer
1105 underlying GaN layer
1106 channel GaN layer
1107 2DEG barrier layer
1110 GaN based layered body
1111 2DEG layer
1121 orientation flat portion
1201 source electrode
1202 gate electrode
1203 drain electrode
1301 step
1302 terrace

1.-11. (canceled)

12. A nitride semiconductor layered body comprising:
a Si substrate having a surface, as a principal surface, inclined at an off-angle of 0.8 degrees or more and 2.7 degrees or less with respect to a (111) plane; and
a nitride semiconductor layer disposed on the Si substrate.

13. The nitride semiconductor layered body according to claim 12,
wherein the nitride semiconductor layer includes an AlN layer disposed on the principal surface of the Si substrate, and
the thickness of the AlN layer is 50 nm or more and 400 nm or less.

14. The nitride semiconductor layered body according to claim 13,
wherein the half-width of a rocking curve based on X-ray diffraction of a (0002) plane of the AlN layer is 2,500 arcsec or less.

15. The nitride semiconductor layered body according to claim 13, comprising:
at least one AlGaN layer disposed on the AlN layer; and
a GaN layer disposed on the AlGaN layer,
wherein the Al composition ratio in the AlGaN layer is 10% or more and 80% or less, and
the thickness of the GaN layer is 100 nm or more.

16. A method for manufacturing a nitride semiconductor layered body, the method comprising the step of
forming a nitride semiconductor layer on a Si substrate through epitaxial growth,
wherein a principal surface of the Si substrate has an off-angle of 0.8 degrees or more and 2.7 degrees or less with respect to a (111) plane.

17. A nitride semiconductor device comprising:
the nitride semiconductor layered body according to claim 12; and
a source electrode and a drain electrode disposed on the nitride semiconductor layer and arranged at a predetermined distance from each other,
wherein a straight line on the (111) plane of the Si substrate in the direction at an angle of 0 degrees or more and 30 degrees or less with respect to a straight line in the direction from the barycenter of the source electrode toward the barycenter of the drain electrode is specified as a rotation axis of the off-angle.

18. The nitride semiconductor device according to claim 17,
wherein an AlN layer serving as the nitride semiconductor layer and having a layer thickness of 30 nm or more and 400 nm or less is stacked on the Si substrate.

19. The nitride semiconductor device according to claim 18,
wherein the half-width of a rocking curve based on X-ray diffraction of the (0002) plane of the AlN layer is 2,500 arcsec or less.

20. The nitride semiconductor device according to claim 18,
wherein at least one AlGaN layer serving as the nitride semiconductor layer and having an Al composition of 10% or more and 80% or less is stacked on the AlN layer, and
a GaN layer serving as the nitride semiconductor layer and having a layer thickness of 100 nm or more is stacked on the AlGaN layer.

21. The nitride semiconductor layered body according to claim 14, comprising:
at least one AlGaN layer disposed on the AlN layer; and
a GaN layer disposed on the AlGaN layer,
wherein the Al composition ratio in the AlGaN layer is 10% or more and 80% or less, and
the thickness of the GaN layer is 100 nm or more.

22. The nitride semiconductor device according to claim 19,
wherein at least one AlGaN layer serving as the nitride semiconductor layer and having an Al composition of 10% or more and 80% or less is stacked on the MN layer, and
a GaN layer serving as the nitride semiconductor layer and having a layer thickness of 100 nm or more is stacked on the AlGaN layer.
